(19) United States
(12) Patent Application Publication
(10) Pub. No.: US 2026/0162844 A1
(43) Pub. Date: Jun. 11, 2026

(54) Stack-Type Isotope Battery

(71) Applicant: LG Energy Solution, Ltd., Seoul (KR)

(72) Inventors: Dong Myung Kim, Daejeon (KR); Je Young Kim, Daejeon (KR); Dong Myung Shin, Daejeon (KR); Young Min Cho, Daejeon (KR)

(73) Assignee: LG Energy Solution, Ltd., Seoul (KR)

(21) Appl. No.: 19/293,637

(22) Filed: Aug. 7, 2025

Related U.S. Application Data
(63) Continuation of application No. 19/276,274, filed on Jul. 22, 2025.

(30) Foreign Application Priority Data
Jul. 22, 2024 (KR) 10-2024-0096587
Jul. 18, 2025 (KR) 10-2025-0097316

(51) Int. Cl. G21H 1/06; H10B 80/00; H10W 42/00; H10W 90/00; H10W 90/20

(52) U.S. Cl. CPC G21H 1/06; H10B 80/00; H10W 42/00; H10W 90/00; H10W 90/297

(57) ABSTRACT

An isotope battery may include a plurality of isotope battery sheets that are stacked in a first direction, a first external electrode, and a second external electrode. Each isotope battery sheet of the plurality of isotope battery sheets includes: a substrate including a semiconductor material; and a radiation source. The radiation source may extend through at least a portion of the substrate in the first direction. The substrate includes a first region having a first conductive type and a second region having a second conductive type. The first region may be between the radiation source and the second region. The first external electrode and the second external electrode are configured to transfer electrical energy generated by the plurality of stacked isotope battery sheets to an external load. The isotope battery has the effect of generating electrical energy with a high energy density.

### CROSS-REFERENCE TO RELATED APPLICATIONS

This application claims priority under 35 U.S.C. § 119 to Korean Patent Application No. 10-2024-0096587, filed on Jul. 22, 2024 and Korean Patent Application No. 10-2025-0097316, filed on Jul. 18, 2025, and the entire contents of each of which are incorporated herein by reference.

### TECHNICAL FIELD

The present disclosure relates to an isotope battery.

### BACKGROUND

An isotope battery is a battery that absorbs radiation emitted by radioactive isotopes through the surface of a p-n junction semiconductor and converts the radiation into electrical energy. The radiation generates electron-hole pairs in the space charge region of the p-n junction semiconductor, and the generated carriers have the voltage-current characteristics of an isotope battery.

### SUMMARY

### Technical Problem

There is a need for isotope batteries with improved energy density. Aspects of the present disclosure are directed to isotope batteries capable of generating electrical energy with increased energy density.

### Technical Solution

To solve the above technical problem, aspects of the present disclosure provide an isotope battery including a plurality of isotope battery sheets that are stacked, each of the plurality of isotope battery sheets including: a semiconductor substrate; and a radiation source penetrating the semiconductor substrate, wherein the semiconductor substrate includes a first region having a first conductive type disposed on a side of the radiation source and a second region having a second conductive type disposed on a side of the first region.

### Advantageous Effects

The isotope battery of the present disclosure has the effect of generating electric energy with a high energy density.

The effects that may be obtained from the isotope batteries of the present disclosure are not limited to those mentioned above, and other effects not mentioned may be clearly derived and understood by one of ordinary skill in the art to which the present disclosure belongs from the following description. That is, unintended effects of practicing aspects of the present disclosure may also be derived from the aspects of the present disclosure by one of ordinary skill in the art.

### BRIEF DESCRIPTION OF THE DRAWINGS

Aspects of the present disclosure will be more clearly understood from the following detailed description in conjunction with the accompanying drawings in which:

FIGS. 1a and 1b are side cross-sectional views illustrating an isotope cell according to aspects of the present disclosure.

FIGS. 2a to 2c are plan views of isotope battery sheets according to aspects of the present disclosure.

FIGS. 3a and 3b are plan views of isotope battery sheets according to aspects of the present disclosure.

FIGS. 4 and 5 are side cross-sectional views of an isotope battery according to aspects of the present disclosure.

FIG. 6a is a side cross-sectional view of an isotope battery according to an aspect of the present disclosure.

FIG. 6b is a plan view of an isotope battery sheet according to an aspect of the present disclosure.

FIG. 6c is a side cross-sectional view of an isotope battery sheet according to an aspect of the present disclosure.

FIG. 7 is an exploded schematic view of an isotope battery according to an aspect of the present disclosure.

FIG. 8 schematically depicts a non-volatile memory device according to an aspect of the present disclosure.

FIG. 9 is a side cross-sectional view of an isotope battery according to an aspect of the present disclosure.

FIG. 10a is a side cross-sectional view of an isotope battery according to an aspect of the present disclosure.

FIG. 10b is a perspective view of the first region, radiation source, and insulating layer of an isotope battery sheet according to an aspect of the present disclosure.

FIG. 11 is a side cross-sectional view of an isotope battery according to an aspect of the present disclosure.

Like reference numerals and designations refer to the same elements in the figures. Additionally, various elements and areas of the figures are schematically depicted and are not necessarily drawn to scale. Accordingly, the aspects of the present disclosure are not limited to the relative sizes or spacing depicted in the accompanying drawings.

### DETAILED DESCRIPTION

Hereinafter, aspects of the present disclosure will be described in detail with reference to the accompanying drawings. However, the aspects of the present disclosure may be modified in many ways, and it should be understood that the scope of the present disclosure is not limited to the aspects described below. The aspects of the present disclosure are described herein to more fully explain the concepts of the present disclosure to one of ordinary skill in the art.

Terms such as “first,” “second,” and the like may be used to describe various components, but the components are not limited by such terms. These terms are used only for the purpose of distinguishing one component from another and do not imply order, sequence, or total number of components unless the context clearly indicates otherwise. For example, a first component may be named a second component, and vice versa, a second component may be named a first component, without departing from the scope of the present disclosure.

Expressions in the singular include the plural unless the context clearly indicates otherwise. In this application, expressions such as “includes” or “has” are intended to designate the presence of the features, numbers, steps, operations, components, parts, or combinations thereof described, and are not to be understood as precluding the possibility of the presence or addition of one or more other features, numbers, operations, components, parts, or combinations thereof.

Unless otherwise defined, all terms used herein, including technical and scientific terms, shall have the same meaning as commonly understood by one of ordinary skill in the art to which the present disclosure belongs. It is further understood that such terms, as commonly used and as defined in dictionaries, are to be construed to have a meaning consistent with their meaning in the context of the art to which they relate and are not to be construed in an unduly formal sense unless expressly defined herein.

Some aspects of the present disclosure can be implemented differently, and certain processes may be performed in a sequence other than that described. For example, two consecutively described process steps may be performed substantially simultaneously, or in the opposite order from the order described.

In the accompanying drawings, variations in the illustrated shapes may be expected, for example, due to manufacturing techniques and/or tolerances. Accordingly, aspects of the present disclosure should not be construed as limited to the specific shape of the areas shown herein, and should include, for example, variations in shape resulting from manufacturing processes.

The term “and/or” used herein include each and every combination of one or more of the components mentioned. Further, the term “substrate” as used herein may refer to the substrate itself, or to a laminated structure including the substrate and any predetermined layers or films formed on its surface. Further, as used herein, the term “surface of the substrate” may refer to the exposed surface of the substrate itself, or to the outer surface of a predetermined layer or film formed on the substrate.

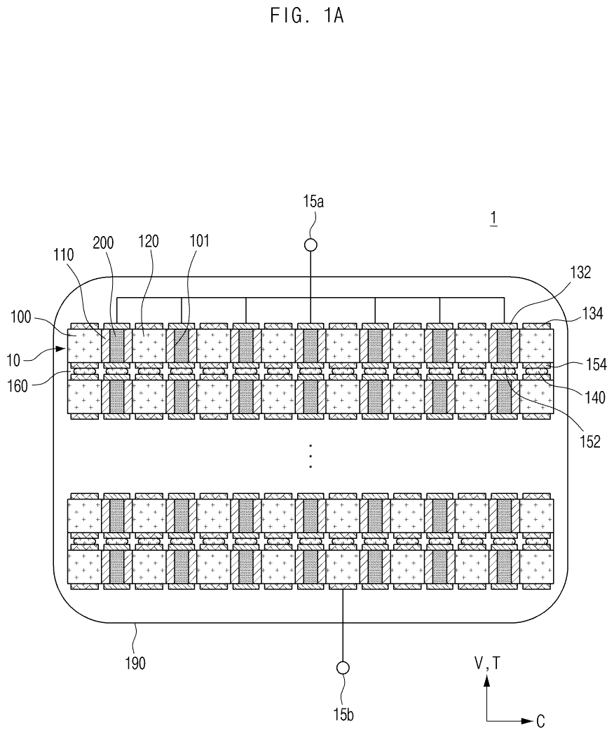

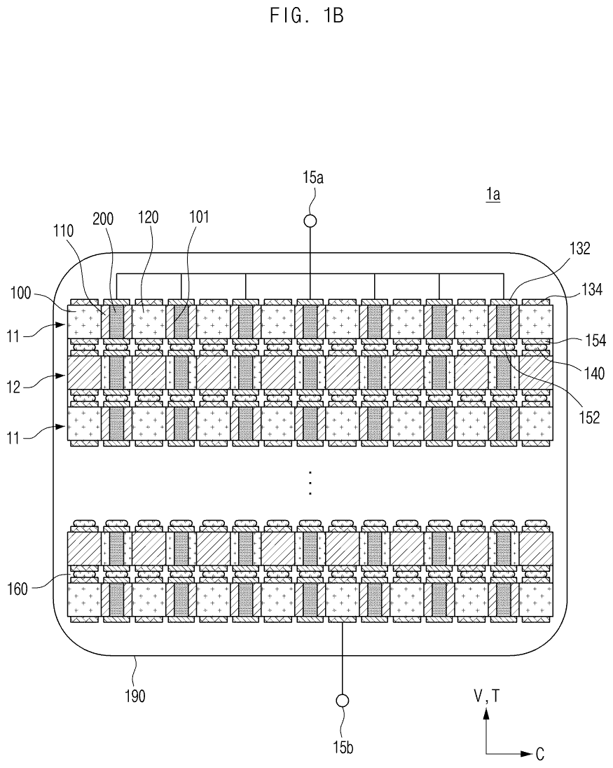

FIG. 1a is a side cross-sectional view illustrating an isotope battery 1 according to an aspect of the present disclosure.

Referring to FIG. 1a, the isotope battery 1 may include a plurality of isotope battery sheets 10 that are stacked on each other to form a layered structure. The plurality of isotope battery sheets may be stacked on each other in a vertical direction V, or a substrate thickness direction T. In the aspect depicted in FIG. 1, the vertical direction V may be the same as the substrate thickness direction T. In one or more aspects, the isotope battery may comprise greater than or equal to 2 isotope battery sheets 10. For example, the number of isotope battery sheets 10 may be greater than or equal to 2, 3, 4, 5, 6, 7, 8, 9, 10, 15, 20, 25, or 30.

Each of the plurality of isotope battery sheets 10 may include a substrate 100 and a radiation source 200.

The substrate 100 may comprise a first surface and a second surface opposite the first surface in the substrate thickness direction T. The first surface and the second surface may be the top and bottom major surfaces of the substrate 100, respectively. A thickness of the substrate refers to an average distance from the first surface of the substrate to the second surface of the substrate in the substrate thickness direction T.

The radiation source 200 may penetrate at least a portion of the substrate 100. In one or more aspects, the radiation source 200 may extend through at least a portion of the substrate 100 in the substrate thickness direction. The radiation source 200 may extend through an entire thickness of the substrate 100. In such aspects, the radiation source 200 may extend from the first surface to the second surface of the substrate 100. In some aspects, the radiation source 200 may extend through a portion of the substrate 100. For example, the radiation source 200 may extend from the first surface of the substrate 100 toward the second surface of the substrate 100 in the substrate thickness direction T. In another example, the radiation source 200 may extend from the second surface of the substrate 100 toward the first surface of the substrate 100 in the substrate thickness direction T.

In one or more aspects, the radiation source 200 may be disposed in a through hole 101 of the substrate 100. The through hole 101 may extend from the first or second surface of the substrate toward the opposite surface of the substrate. The through hole 101 may extend in the substrate thickness direction T. The through hole 101 may have an opening at the first surface of the substrate 100, the second surface of the substrate 100, or both the first surface and the second surface of the substrate 100. In the aspect depicted in FIG. 1a, the through hole 101 extends from the first surface of the substrate 100 to the second surface of the substrate 100 in the substrate thickness direction T and has openings at both the first and second surfaces of the substrate 100.

In one or more aspects, the radiation source 200 may be disposed between the first surface and the second surface of the substrate 100. In such aspects, the space between isotope battery sheets 10 in the isotope battery 1 may be free from the radiation source.

The substrate 100 may include a first region 110 and a second region 120. The first region 110 may be between the radiation source 200 and the second region 120.

As schematically depicted in FIG. 1a, the first region 110 and the second region 120 may be adjacent to one another. The first region 110 and the second region 120 may be repeatedly and/or alternately disposed in a substrate transverse direction C, which is perpendicular to the substrate thickness direction T. In one or more aspects, an interface between the first region 110 and the second region 120 may extend from the first surface of the substrate 100 to the second surface of the substrate 100. In some aspects, the interface between the first region 110 and the second region 120 may extend in the substrate thickness direction T. The first region 110 and the second region 120 may form a p-n junction at the interface.

In some aspects, the substrate 100 may include a semiconductor material. For example, the substrate may comprise III-V group semiconductor materials. The III-V group semiconductor materials may include InAlP, InGaP, InAlGaP, ZnSe, AlAs, AlAsP, or yttria-stabilized zirconia (YSZ).

In some aspects, the substrate 100 may include a diamond substrate, a SiC substrate, a GaN substrate, a Bi₂O₃/GeO₂ substrate, a Sm₂O₃/Bi₂O₃/GeO₂ substrate, a Sm₂O₃/Bi₂O₃/B₂O₃ substrate, Sm₂O₃/Bi₂O₃/GeO₂/B₂O₃ substrate, sapphire substrate, or a combination thereof. In some aspects, the substrate may be undoped. An undoped substrate is free or substantially free of dopants. A substrate is “substantially free” of a dopant when no dopant is intentionally added to the substrate. In some aspects, the substrate may be doped with a dopant.

In other aspects, the substrate 100 may have the chemical formula AMO₃ where A is one or more elements selected from the group consisting of La, Ba, Sr, and K, and M is one or more elements selected from the group consisting of Al, In, Ga, Ti, Sn, Hf, Ta, and Zr.

In one or more aspects, the substrate 100 may comprise one or more of BaSnO₃, BaHfO₃, BaZrO₃, BaHf₁₋ₓTiₓO₃ (where 0<x<1), Ba₁₋ₓLaₓSnO₃ (where 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂ LaInO₃, LaGaO₃, SrZrO₃, SrHfO₃, SrTaO₇, LaIn₁₋ₓGaₓO₃ (where 0<x<1), LaGaO₃, SrTiO₃, KTaO₃, HfSiO₄, Ta₃Ti₂Oₓ, or LaAlO₃ (where 0<x<1).

In some aspects, the substrate 100 may comprise a semiconductor substrate. In some aspects, the substrate 100 may comprise an insulating substrate.

In some aspects, the first region 110 may include a metal oxide having a bandgap energy of 2.7 eV or more. In some aspects, the metal oxide may have the chemical formula AMO₃ where A is one or more elements selected from the group consisting of La, Ba, Sr, and K, and M is one or more elements selected from the group consisting of Al, In, Ga, Ti, Sn, Hf, Ta, and Zr.

In one or more aspects, the metal oxide in the first region 110 may include one or more of BaSnO₃, BaHfO₃, BaZrO₃, BaHf₁₋ₓTiₓO₃ (where 0<x<1), Ba₁₋ₓLaₓSnO₃ (where 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂, LaInO₃, LaGaO₃, SrZrO₃, SrHfO₃, SrTaO₇, LaIn₁₋ₓGaₓO₃ (where 0<x<1), LaGaO₃, SrTiO₃, KTaO₃, HfSiO₄, Ta₄Ti₂Oₓ, and LaAlO₃ (where 0<x<1).

The metal oxides are not only stable in high-temperature and high-humidity environments but also have high carrier mobility, enabling them to efficiently absorb radiation emitted from the radiation source 200 and/or photons emitted from the subsequently described photon generating layer 250, thereby providing high energy conversion efficiency. Additionally, there are no inelastic collisions in carrier mobility, resulting in no energy loss and favorable heat dissipation. For example, the metal oxides can have carrier mobility of greater than or equal to 45 cm²/(V·s), greater than or equal to 80 cm²/(V·s), greater than or equal to 120 cm²/(V·s), or even greater than or equal to 300 cm²/(V·s).

These metal oxides are materials that can be doped in any conductivity type and have the advantage of being able to provide high current or high voltage depending on the direction of the applied bias.

Still referring to FIG. 1a, the first region 110 and the second region 120 of the substrate 100 can generate electron-hole pairs from radiation emitted by the radiation source 200. In some aspects, the first region 110 and the second region 120 of the substrate 100 may comprise an inorganic layer, an organic layer, a dye sensitized layer, or a combination thereof, and the first region 110 and the second region 120 may generate power by forming electron-hole pairs from radiation emitted by the radiation source 200.

In one or more aspects, the first region 110 may be doped with a dopant of a first conductive type. The second region 120 may be doped with a dopant of the second conductive type. In some aspects, the first conductive dopant may be an n-type dopant and the second conductive dopant may be a p-type dopant. In some other aspects, the dopant of the first conductive type may be a p-type dopant and the dopant of the second conductive type may be an n-type dopant. Depending on the conductivity type of the dopants doped in each region, one of the first region 110 and the second region 120 may act as a cathode and the other may act as an anode. That is, if the dopant of the first conductive type is n-type dopant and the dopant of the second conductive type is p-type dopant, then the first region 110 may act as an anode and the second region 120 may act as a cathode. Conversely, if the dopant of the first conductive type is a p-type dopant and the dopant of the second conductive type is an n-type dopant, the first region 110 can act as a cathode and the second region 120 can act as an anode.

The n-type doped region may be, for example, silicon or diamond doped with nitrogen (N), phosphorus (P), arsenic (As), or antimony (Sb), which are Group 15 elements of the periodic table, or it may be a compound semiconductor doped with nitrogen (N), phosphorus (P), arsenic (As), or antimony (Sb), which are Group 15 elements of the periodic table. As used herein, a compound semiconductor refers to a semiconductor composed of two or more elements, such as silicon carbide, silicon oxide, aluminum phosphide (AlP), aluminum arsenide (AlAs), gallium arsenide (GaAs), or gallium nitride (GaN). In some aspects, the n-type dopants may include silicon (Si), germanium (Ge), or tellurium (Te).

The p-type doped region may be, for example, silicon or diamond doped with any of the Group 13 elements of the periodic table, such as boron (B), aluminum (Al), gallium (Ga), or indium (In), or may be a compound semiconductor doped with any of the boron group elements of the periodic table, such as boron (B), aluminum (Al), gallium (Ga), or indium (In). In some aspects, the p-type dopants may include beryllium (Be), magnesium (Mg), or zinc (Zn).

In some aspects, the first region 110 or the second region 120 or both the first region 110 and the second region 120 may include an organic material. The organic material may be used in organic layers that receive light to generate power, such as in solar cell applications. For example, the first region 110 and the second region 120 may include a thiophene-like compound. In some aspects, the first region 110, the second region 120, or both may be inorganic-organic hybrids, including any suitable mix of inorganic and organic materials described above.

In some aspects, a depletion region may be formed near the interface where the first region 110 and the second region 120 contact each other.

In some aspects, the radiation source 200 may be positioned within a through-hole 101 penetrating at least a portion of the substrate 100. The through-hole 101 may comprise an opening in the first surface of the substrate 100. In one or more aspects, the radiation source 200 may partially or completely fill the through-hole 101. In some aspects, the radiation source 200 may be in contact with a circumference of the through-hole 101. For example, in some aspects, the radiation source 200 may completely fill a through-hole 101 having a circular cross-sectional shape such that the radiation source 200 has a cylindrical shape. In other aspects, the radiation source 200 may partially fill a through-hole 101 having a circular cross-sectional shape such that the radiation source 200 has an annular shape.

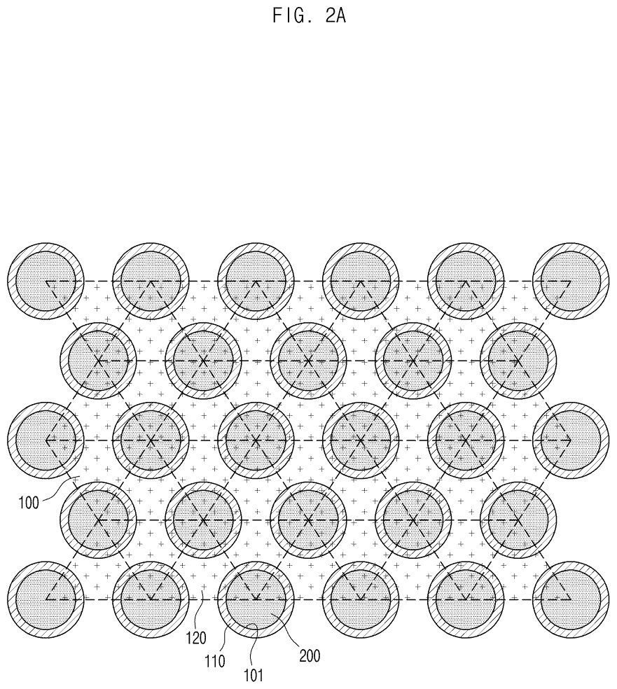

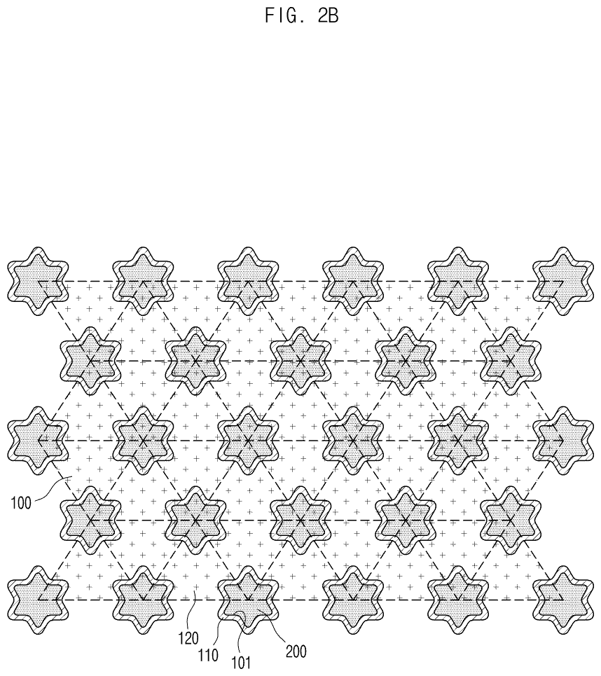

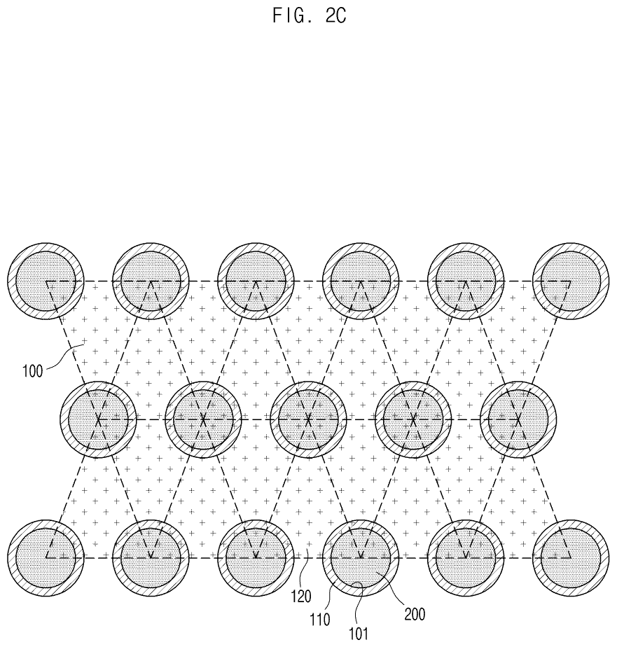

FIGS. 2a to 2c are plan views illustrating configuration in which the radiation source 200 may be disposed in the through-hole 101 according to aspects of the present disclosure.

Referring to FIG. 2a, the substrate 100 is provided with a plurality of through-holes 101 penetrating through the substrate 100, and the radiation source 200 may be disposed within the through-holes 101. The through-holes 101, as shown in FIG. 2a, may have a circular cross-section. However, the cross-sectional shape of the through-holes 101 is not limited to a circle. For example, the through-holes 101 may have a cross-sectional shape of a circle, an oval, an ellipse, a triangle, a rectangle, a pentagon, a hexagon, any regular polygon, any irregular polygon, or any closed shape.

The through-holes 101 may be formed by any method known to those skilled in the art. For example, the through-holes 101 may be formed by methods such as anisotropic etching, isotropic etching, or laser irradiation. In some aspects, the through-holes 101 may be formed by irradiating the substrate 100 with laser light. In some aspects, the through-holes 101 may be formed by reactive ion etching (RIE).

In some aspects, the through-holes 101 may be arranged with a predetermined regularity or pattern. The pattern may be in a plane normal to the vertical direction V. In one or more aspects, the through-holes 101 may be arranged at the vertices of a series of equilateral or isosceles triangles, rectangles, squares, diamonds, trapezoids, or any other suitable shape. In some aspects, the through-holes 101 may be arranged such that gaps between neighboring through-holes 101 are approximately the same size resulting a regular or consistent distribution of radiation source 200 in the isotope battery sheet 10. In some aspects, the through-holes 101 may be disposed so that their respective centers are located at the vertices of a series of imaginary equilateral triangles. By disposing the through-holes 101 so that their centers are located at the vertices of the imaginary equilateral triangles, the number of radiation sources 200 that can be accommodated per unit area can be maximized. Therefore, energy density of the isotope battery 1 can be further increased.

In some aspects, the first region 110 may be disposed to surround a side of the radiation source 200. In some aspects, the second region 120 may be disposed to surround a side of the first region 110. Referring to FIG. 2a, the first region 110 is in an annular shape to surround each radiation source 200, and the second region 120 surrounds the annual first region 110. In some aspects, the first region 110 may include one type of semiconductor material, and the second region 120 may include another type of semiconductor material.

Referring to FIG. 2b, the side walls of the through-holes 101 may have irregularities. That is, the through-holes 101 may have concave portions and convex portions. The interface between the radiation source 200 and the first region 110 may have irregularities. In some aspects, the interface between the first region 110 and the second region 120 may have irregularities.

The first region 110 may have a substantially constant lateral thickness as shown in FIG. 2b. Accordingly, the interface between the first region 110 and the second region 120 may have a shape corresponding to the interface between the radiation source 200 and the first region 110.

The side walls of the through-holes 101 may have irregularities, thereby increasing the contact area between the radiation source 200 and the first region 110, and thus improving the efficiency of the radiation source 200. Additionally, the interface between the first region 110 and the second region 120 may have a corrugated shape, which increases the contact area between the first region 110 and the second region 120, thereby improving the efficiency of the isotope battery 1. As an example, the irregularities illustrated in FIG. 2b may be in the form of repeating corrugations extending linearly along the vertical direction V or the thickness direction T.

Referring to FIG. 2c, the centers of the through-holes 101 may be arranged such that they are located at the vertices of a series of virtual isosceles triangles. As shown in FIG. 2a, the centers of the through-holes 101 need not necessarily be located at the vertices of a series of virtual equilateral triangles.

In some aspects, the triangles in which the centers of the through-holes 101 are disposed may have different shapes. Accordingly, the through-holes 101 may be arranged somewhat irregularly.

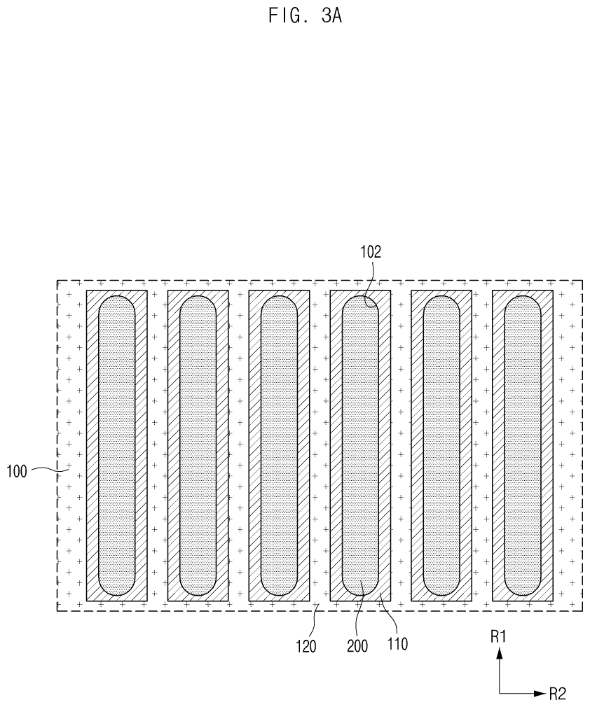

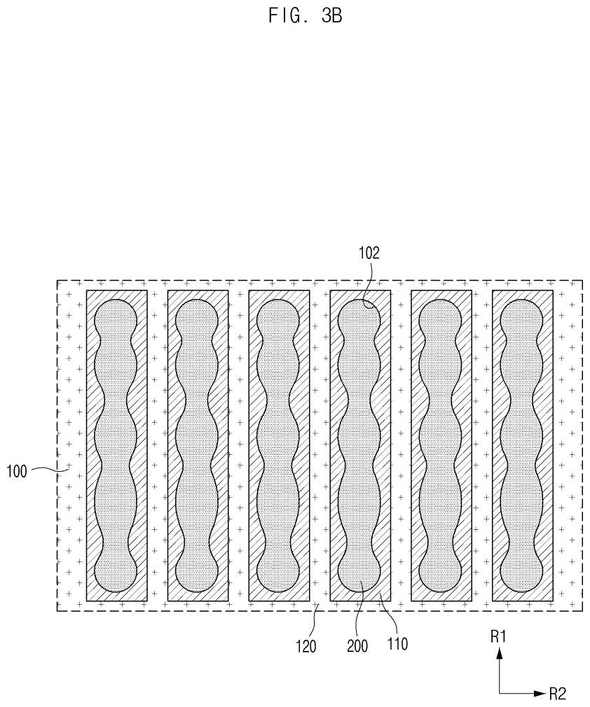

In some aspects, the radiation source 200 may be disposed within a slit extending into the substrate 100. FIGS. 3a and 3b are plan views illustrating configurations in which the radiation source 200 may be disposed in the slit 102 according to the aspects of the present disclosure.

Referring to FIG. 3a, the substrate 100 may include a plurality of slits 102 extending in parallel in a first direction R1. Each of the plurality of slits 102 may be elongated in a second direction R2 that is perpendicular to the first direction R1. The first direction R1 and the second direction R2 are perpendicular to the substrate thickness direction T. Further, a radiation source 200 may be provided within each of the plurality of slits 102. As shown in FIG. 3a, the slits 102 may have a length in the first direction R1 that is greater than a width of the slit 102 in the second direction R2.

In some aspects, a side of the radiation source 200 may contact a side of each of the plurality of slits 102. The radiation source 200 may be in contact with a perimeter of each of the plurality of slits 102.

In some aspects, the first region 110 may face an extended side of the radiation source 200. The first region 110 may face both extended sides of the radiation source 200. For example, the first region 110 may extend along two longitudinal sides of the slit 102 extending in the first direction R1. As exemplarily shown in FIG. 3a, the first region 110 may completely surround the slit 102. In one or more aspects, the first region 110 may be disposed to completely or at least partially surround the radiation source 200.

In some aspects, the second region 120 may be disposed to face an extended side of the first region 110. For example, the second region 120 may extend along the part of the first region 110 which extends along the longitudinal side of the slit 102.

In some aspects, the first region 110 may be disposed to surround a side of the radiation source 200. In some aspects, the second region 120 may be disposed to surround a side of the first region 110 at least partially. In some aspects, as shown in FIG. 3a, the second region 120 may completely surround the first region 110.

Referring to FIG. 3b, the side walls of the slits 102 may have irregularities. That is, the side walls of the slits 102 may have concave and convex portions. The interface between the radiation source 200 and the first region 110 may have irregularities.

When the side walls of the slits 102 have irregularities, the contact area between the radiation source 200 and the first region 110 may be increased, thereby improving the efficiency of the radiation source 200. Thus, as an example, the irregularities illustrated in FIG. 3b may be in the form of repeating corrugations extending linearly along the vertical direction V or the thickness direction T.

In FIG. 1a through FIG. 3b, the entire portion of the substrate 100 that is not the first region 110 of the substrate 100 or the radiation source 200 is shown as a second region 120 of the substrate 100, but aspects of the present disclosure are not limited to this configuration. For example, regions of a different conductivity type or of different dopant concentrations may be present in the substrate 100 apart from the second region 120, or regions that are not doped with a particular conductivity may be present in the substrate 100. In some aspects, an electrode may contact a portion of the first region 110 or the second region 120. The portion of the first region 110 or the second region 120 in contact with an electrode may have a different dopant concentration than a dopant concentration in a remainder of that region.

Referring again to FIG. 1a, each isotope battery sheet of the plurality of isotope battery sheets 10 may be substantially identical. For example, each isotope battery sheet may have an identical semiconductor die. Each isotope battery sheet 10 of the plurality of isotope battery sheets 10 may include a first upper electrode 132 at an upper part of the first region 110 and a first lower electrode 152 at a lower part of the first region 110. In one or more aspects, the first upper electrode 132 may be in electrical contact with the first region 110 at the first surface of the substrate 100, and the first lower electrode 152 may be in contact with the first region 110 at the second surface of the substrate 100.

Further, each of the isotope battery sheets 10 may include a second upper electrode 134 at an upper part of the second region 120 and a second lower electrode 154 at a lower part of the second region 120. In one or more aspects, the second upper electrode 134 may be in electrical contact with the second region 120 at the first surface of the substrate 100, and the second lower electrode 154 may be in contact with the second region 120 at the second surface of the substrate 100.

In some aspects, a top-most isotope battery sheet 10 may comprise the first upper electrode 132 and may be free from the second upper electrode 134. In some aspects the top-most isotope battery sheet 10 may comprise the second upper electrode 134 and be free from the first upper electrode 132. In some aspects, a bottom-most isotope sheet 10 may comprise the first lower electrode 152 and may be free from the second lower electrode 154. In some aspects, the bottom-most isotope sheet 10 may comprise the second lower electrode 154 and may be free from the first lower electrode 152. In one or more aspects, a portion of the first region 110 or the second region 120 or both which lacks an electrode may be in contact with a passivation layer.

Each of the first upper electrode 132, the first lower electrode 152, the second upper electrode 134, and the second lower electrode 154 may act as a current collector. Each of the first upper electrode 132, the first lower electrode 152, the second upper electrode 134, and the second lower electrode 154 is not particularly limited in type, size, and shape as long as it is electrically conductive without causing physical and chemical changes to the isotope battery sheet 10. For example, each of the first upper electrode 132, the first lower electrode 152, the second upper electrode 134, and the second lower electrode 154 may be cylindrical, tetrahedral, hexahedral, torus, or pad-shaped. In some aspects, each of the first upper electrode 132, the first lower electrode 152, the second upper electrode 134, and the second lower electrode 154 may have a hollow center portion. In some aspects, at the first surface of the substrate 100, the second upper electrode 134 may be a continuous layer comprising openings arranged corresponding to the first regions 110, and the first upper electrodes 132 may be positioned in said openings. In some aspects, at the second surface of the substrate 100, the second lower electrode 154 may be a continuous layer comprising openings arranged corresponding to the first regions 110, and the first lower electrodes 152 may be positioned in said openings.

In some aspects, each of the first upper electrode 132, the first lower electrode 152, the second upper electrode 134, and the second lower electrode 154 may include a metallic material, a transparent oxide, or a carbon-based compound. The metallic material may comprise gold (Au), silver (Ag), platinum (Pt), stainless steel, copper (Cu), aluminum (Al), nickel (Ni), or titanium (Ti). The transparent oxide may comprise fluorine (F)-doped tin oxide (FTO) or indium tin oxide (ITO, In₂O₃). The carbon-based compound may comprise carbon-nanotubes, graphene, or graphene oxide.

In some aspects, the radiation source 200 may include a radioactive isotope that emits beta rays. For example, the radiation source 200 may include one or more of tritium (³H), calcium-45 (⁴⁵Ca), nickel-63 (⁶³Ni), copper-67 (⁶⁷Cu), strontium-90 (⁹⁰Sr), promethium-147 (¹⁴⁷Pm), osmium-194 (¹⁹⁴Os), thulium-171 (¹⁷¹Tm), thallium-204 (²⁰⁴Tl), tantalum-182 (¹⁸²Ta), cadmium-115 (¹¹⁵Cd), cadmium-113 (¹¹³Cd), germanium-75 (⁷⁵Ge), cerium-141 (¹⁴¹Ce), cerium-144 (¹⁴⁴Ce), or tungsten-185 (¹⁸⁵W). However, aspects of the present disclosure are not limited to these.

In some aspects, the radiation source 200 may include a radioactive isotope that emits alpha rays. For example, the radiation source 200 may include one or more of americium-241 (²⁴¹Am), americium-243 (²⁴³Am), polonium-209 (²⁰⁹Po), polonium-210 (²¹⁰Po), plutonium-238 (²³⁸Pu), plutonium-239 (²³⁹Pu), curium-242 (²⁴²Cm), curium-244 (²⁴⁴Cm), curium-249 (²⁴⁹Cm), promethium-147 (¹⁴⁷Pm), uranium-238 (²³⁸U), thorium-232 (²³²Th), radium-226 (²²⁶Ra), bismuth-210 (²¹⁰Bi), neptunium-237 (²³⁷Np), europium-152 (¹⁵²Eu), francium-223 (²²³Fr), astatine-210 (²¹⁰At), protactinium-231 (²³¹Pa), einsteinium-253 (²⁵³Es), californium-252 (²⁵²⁰Cf), or berkelium-249 (²⁴⁹Bk). However, aspects of the present disclosure are not limited to these.

The radiation source 200 may be formed by any suitable method known to those skilled in the art. For example, the radiation source 200 may be formed by various methods such as plating, vapor deposition, atomic layer deposition (ALD), etc.

In some aspects, the radiation source 200 may be formed by plating. When the radiation source 200 is formed by plating, a seed layer may be formed, followed by electroplating to form the radiation source 200. In some aspects, the radiation source 200 may be formed by electroless plating.

The first lower electrode 152 of an isotope battery sheet 10 may be electrically connected to the first upper electrode 132 of an adjacent, lower isotope battery sheet 10. In some aspects, the first lower electrode 152 of the isotope battery sheet 10 and the first upper electrode 132 of the adjacent, lower isotope battery sheet 10 may be connected by a connector 140, such as a solder ball.

In one or more aspects, the second lower electrode 154 of an isotope battery sheet 10 may be electrically connected to the second upper electrode 134 of an adjacent, lower isotope battery sheet 10. In some aspects, the second lower electrode 154 of the isotope battery sheet 10 and the second upper electrode 134 of the adjacent, lower isotope battery sheet 10 may be connected by a connector 140, such as a solder ball.

In some aspects, the connector 140 may include a conductive material. The conductive material may comprise one or more of tin (Sn), indium (In), bismuth (Bi), antimony (Sb), copper (Cu), silver (Ag), zinc (Zn), or lead (Pb). The number, spacing, arrangement, and shape of the connectors 140 may be varied by design, without limitation to those shown. Referring to FIGS. 1a and 1b, the connectors 140 may have the shape of solder balls or solder bumps.

In some aspects, a first type of connector may connect the first lower electrode 152 of an isotope battery sheet 10 and a first upper electrode 132 of an adjacent, lower isotope battery sheet 10, and a second type of connector may connect the second lower electrode 154 of the isotope battery sheet 10 and a second upper electrode 134 of the adjacent, lower isotope battery sheet 10. In some aspects, the first type of connector and the second type of connector may have different shapes or different sizes. In some aspects, the first type of connector and the second type of connector may comprise the same material or different materials.

The space between two vertically neighboring isotope battery sheets 10 may be filled by an insulator 160. The insulator 160 is not limited as long as it is any material having electrically insulating properties. For example, the insulator 160 may include one or more of silicate (e.g., TEOS), silicon nitride (SiN), hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, barium titanium oxide, strontium titanium oxide, yttrium oxide, or aluminum oxide. In some aspects, the insulator 160 may include one or more selected f of strontium titanium oxide, yttrium oxide, or aluminum oxide. In some aspects, the insulator 160 may comprise a passivation layer.

The isotope battery 1 shown in FIG. 1a can be obtained by manufacturing individual isotope battery sheets 10 and then stacking them. By manufacturing individual isotope battery sheets 10 and then stacking them, defective isotope battery sheets 10 can be selectively excluded from the stacking process, thereby improving the manufacturing yield of the isotope battery 1 and reducing manufacturing costs.

The plurality of isotope battery sheets 10 may be housed within a housing 190. The plurality of isotope battery sheets 10 may be electrically connected to an external load by conductors drawn out to the outside through the housing 190. For example, first outer electrode 15a and second outer electrode 15b may electrically connect the plurality of isotope battery sheets 10 to an external load.

In some aspects, the housing 190 may further include an electromagnetic interference (EMI) shield (not shown) capable of shielding electromagnetic waves from entering or exiting the housing 190. The EMI shield may be formed on at least a portion of an inner surface and/or an outer surface of the housing 190. The EMI shield may include, for example, a metal such as copper or aluminum, a conductive polymer such as polyaniline, or a magnetic material such as iron oxide. The EMI shield may be a sheet, mesh, applied layer, spray coating, non-woven fabric, tape, or fabric layer. By providing the housing 190 with an EMI shield, the electromagnetic compatibility (EMC) of the isotope battery 1 can be ensured. In addition, in some aspects, the EMI shield can prevent or otherwise restrict beta rays or other radiation (e.g., alpha rays or gamma rays) from exiting the housing.

Referring again to FIG. 1a, the first upper electrodes 132 of the topmost isotope battery sheet 10 may be electrically connected to each other and electrically connected to a first outer electrode 15a of a first polarity. The second lower electrodes 154 of the lowest isotope battery sheet 10 may be electrically connected to a second outer electrode 15b of a second polarity. The first outer electrode 15a and second outer electrode 15b may be exposed to the outside of the housing 190 for connection to an external load.

In some aspects, the second lower electrodes 154 of the isotope battery sheet 10 disposed at the lowest part in FIG. 1a may be electrically connected to each other by surrounding the first lower electrode 152 on the second surface of the substrate 100. In some aspects, the second lower electrodes 154 may be electrically connected to each other by separate conductive lines (not shown) and to the second outer electrode 15b exposed outside the housing 190. The external load may include one or more of an electronic device, an electro-chemical battery, an energy storage devise or any other suitable device. In the aspect of the present disclosure depicted in FIG. 1a, the p-n junctions included in the plurality of isotope battery sheets 10 are connected in parallel such that the output electrical current flowing through the first outer electrode 15a and the second outer electrode 15b is a sum of the individual currents of each p-n junction in each of the plurality of isotope battery sheets 10.

FIG. 1b is a side cross-sectional view of an isotope battery 1a according to another aspect of the present disclosure.

Referring to FIG. 1b, the isotope battery 1a may comprise a first isotope battery sheet 11 and a second isotope battery sheet 12 alternately and repeatedly stacked. The number of first isotope battery sheets 11 included in the isotope battery 1a is not necessarily limited. For example, the isotope battery 1a may comprise at least 2, 3, 4, 5, 6, 7, 8, 9, or 10 of the first isotope battery sheets 11. Likewise, the number of second isotope battery sheets 12 included in the isotope battery 1a is not necessarily limited. For example, the isotope battery 1a may comprise at least 2, 3, 4, 5, 6, 7, 8, 9, or 10 of the second isotope battery sheets 12. In some aspects, the uppermost battery sheet of the isotope battery 1a may be a first isotope battery sheet 11. In some aspects, uppermost battery sheet of the isotope battery 1a may be a second isotope battery sheet 12. In some aspects, a lowermost battery sheet of the isotope battery 1a may be a first isotope battery sheet 11. In some aspects, a lowermost battery sheet of the isotope battery 1a may be a first isotope battery sheet 12. The uppermost and lowermost battery sheets of the isotope battery 1a may be the same or different, provided that the first isotope battery sheets 11 and the second isotope battery sheets are alternately stacked in the isotope battery 1a.

The first isotope battery sheet 11 is substantially the same as the isotope battery sheet 10 described with reference to FIG. 1a, and therefore will not be described in further detail herein.

The second isotope battery sheet 12 comprises components that are substantially identical to each component of the first isotope battery sheet 11, except that the conductivity of the dopants is reversed. That is, if the first region 110 of the first isotope battery sheet 11 is p-type doped, the first region 110 of the second isotope battery sheet 12 may be n-type doped. Conversely, if the first region 110 of the first isotope battery sheet 11 is n-type doped, the first region 110 of the second isotope battery sheet 12 may be p-type doped.

Similarly, if the second region 120 of the first isotope battery sheet 11 is p-type doped, the second region 120 of the second isotope battery sheet 12 may be n-type doped. Conversely, if the second region 120 of the first isotope battery sheet 11 is n-type doped, the second region 120 of the second isotope battery sheet 12 may be p-type doped.

The isotope battery 1a shown in FIG. 1b can obtain higher voltage electrical energy because the number of unit cells corresponding to individual radiation sources 200 is increased and the individual p-n junctional are connected in series. The first outer contact 15a and the second outer contact 15b can have a higher operating voltage than in the isotope battery 1 of FIG. 1a because in FIG. 1b, the p-n junctions are connected in series so that the overall output voltage is the sum of the individual p-n junction voltages.

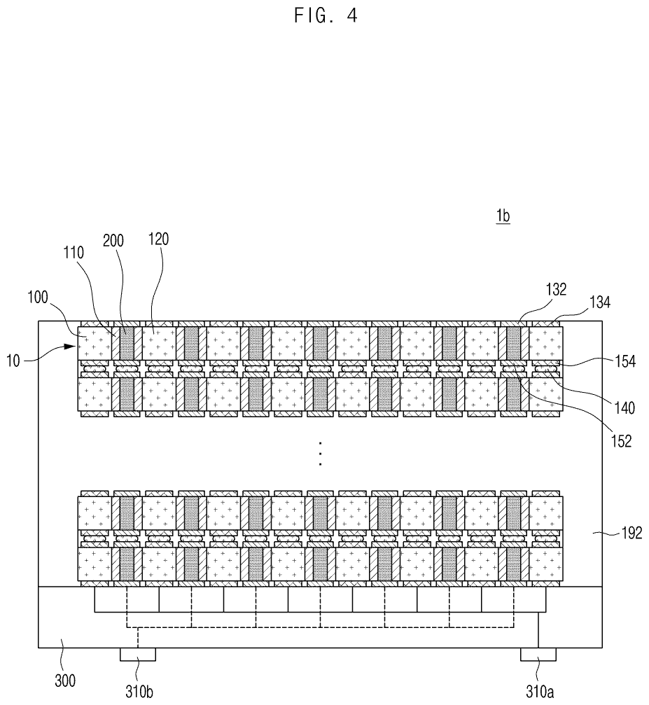

FIG. 4 is a side cross-sectional view illustrating an isotope battery 1b according to an aspect of the present disclosure.

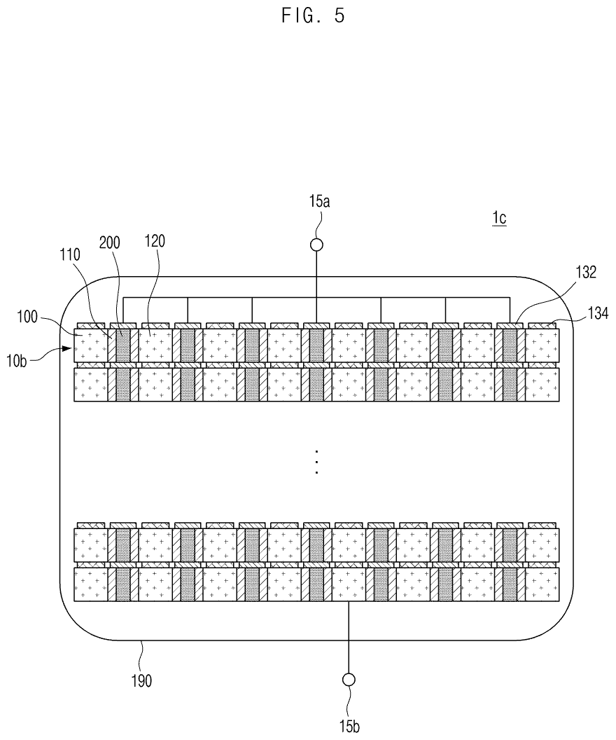

The isotope battery 1b shown in FIG. 4 is substantially the same as the isotope battery 1 described with reference to FIG. 1a through FIG. 3, but differs in that the plurality of isotope battery sheets 10 are enclosed by a molding member 192 and in that the plurality of isotope battery sheets 10 are mounted on the controller chip 300. Accordingly, the following discussion will focus on these differences and omit discussion of the commonalities. It should be understood that any of the isotope batteries 1, 1a of FIGS. 1a to 3b as well as any one of the isotope batteries of FIGS. 5 to 7, 9, and 10a, which are described below, may also be mounted on a controller chip 300 and/or embedded in a molding member 192.

Referring to FIG. 4, the plurality of isotope battery sheets 10 are mounted on a controller chip 300. In some aspects, the controller chip 300 may include a power management integrated circuit (PMIC) that outputs electrical energy generated by the plurality of stacked isotope battery sheets 10 to an external load according to predetermined rules.

The plurality of isotope battery sheets 10 may be at least partially enclosed by a molding resin 192. The molding resin 192 may include, for example, an epoxy molding compound (EMC). In one or more aspects, the molding resin 192 may be between the housing 190 and the plurality of isotope battery sheets 10.

The first upper electrode 132 and the second upper electrode 134 of the topmost isotope battery sheet 10 may act as dummy electrodes when the plurality of isotope battery sheets 10 are electrically connected to the controller chip 300 through the first lower electrode 152 and second lower electrode 154 on the lowermost isotope battery sheet 10, as exemplarily shown in FIG. 4. In some aspects, at least one of the first upper electrode 132 and the second upper electrode 134 of the topmost isotope battery sheet 10 may extend through the molding resin 192 and may be exposed to the outside.

In other aspects, the first upper electrode 132 and the second upper electrode 134 of the topmost isotope battery sheet 10 may be completely covered by the molding member 192. In some aspects, the upper surface of the topmost isotope battery sheet of the plurality of isotope battery sheets 10 lacks both the first upper electrode 132 and the second upper electrode 134 and is instead covered by a passivation layer or by the molding member 192 or by both the passivation layer and the molding member 192.

The electrical energy generated by the plurality of isotope battery sheets 10 may be supplied to an external load via external terminals 310a, 310b provided on the controller chip 300. In FIG. 4, the plurality of isotope battery sheets 10 are shown mounted on the upper part of the controller chip 300, but aspects of the present disclosure are not limited to this configuration.

FIG. 5 is a side cross-sectional view illustrating an isotope battery 1c according to another aspect of the present disclosure.

Referring to FIG. 5, the isotope battery 1c may include a plurality of stacked isotope battery sheets 10b stacked in the vertical direction V, or the substrate thickness direction T.

The isotope battery sheet 10b differs from the isotope battery sheet 10 of FIG. 1a in that the first lower electrode 152, the second lower electrode 154, and the connector 140 are omitted from the isotope battery sheet 10b. Therefore, the following discussion will focus on these differences and omit discussion of the commonalities.

The isotope battery sheet 10b includes a first upper electrode 132 and a second upper electrode 134 on the upper surface of the substrate 100. In some aspects, each isotope battery sheet 10b of the plurality of stacked isotope battery sheets 10b may all have the same type of semiconductor die.

The first upper electrode 132 and the second upper electrode 134 of a first isotope battery sheet 10b may be in direct contact with the bottom surfaces of the first region 110 and the second region 120, respectively, of an isotope battery sheet 10b above and adjacent to the first isotope battery sheet 10b. In other words, on an isotope battery sheet 10b, first upper electrodes 132 and second upper electrodes 134 may only be provided on the first—or top major—surface of the substrate 100, and the second—or bottom major—surface of a substrate 100 of the isotope battery sheet 10b may be in electrical contact with the electrodes 132, 134 on the first—or top major—surface of the substrate 100 of an isotope battery sheet 10b arranged directly thereunder.

The isotope battery 1c may be more compactly configured since the first lower electrodes 152, the second lower electrodes 154, and the connector 140 are omitted, thus increasing the energy density.

In some aspects, first regions 110 of an isotope battery sheets 10b and the second regions 120 of an adjacent isotope battery sheets may be in direct contact with each other, omitting any electrodes between adjacent isotope battery sheets within the stack.

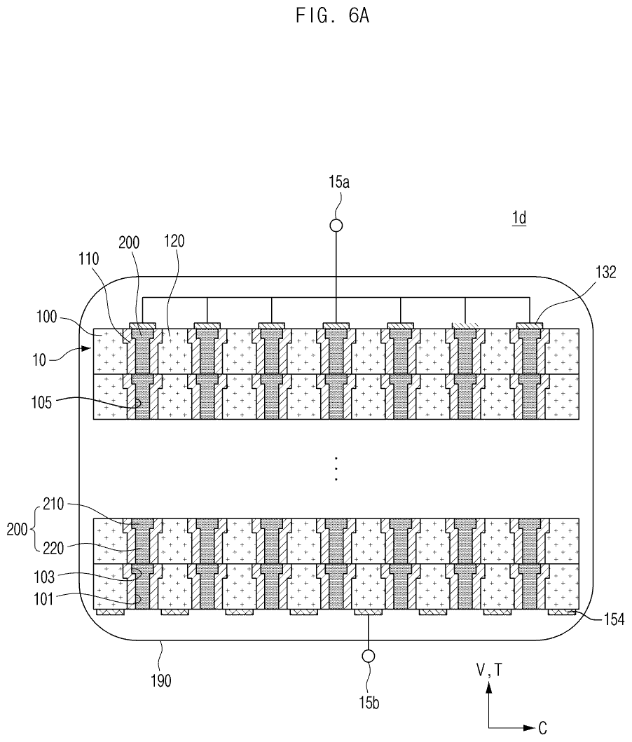

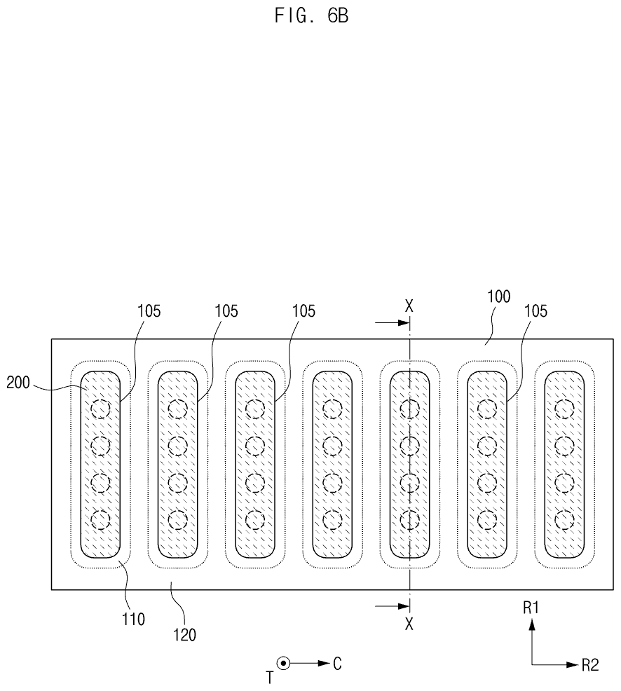

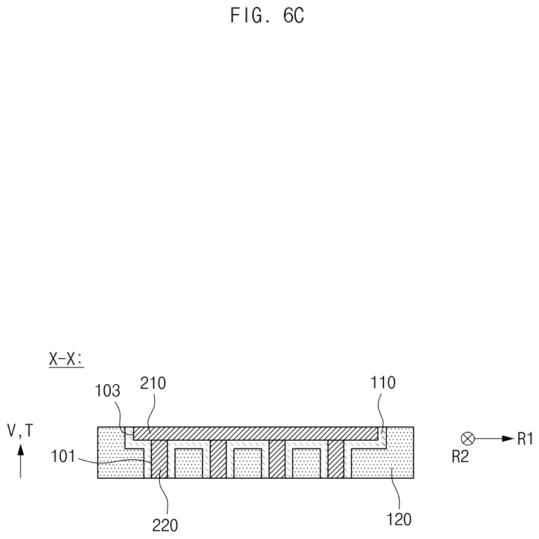

FIG. 6a is a side cross-sectional view illustrating an isotope battery 1d according to another aspect of the present disclosure. FIG. 6b is a plan view of an isotope battery sheet of the isotope battery of FIG. 6a. FIG. 6c is a cross-sectional view along line X-X of FIG. 6b.

Referring to FIG. 6a, the isotope battery 1d may include a plurality of stacked isotope battery sheets 10c. The isotope battery sheets 10c shown in FIGS. 6a, 6b, and 6c differ from those shown in FIG. 1a mainly in the configuration of a cavity 105 in the substrate 100. As exemplarily shown in FIG. 6a, the cavity 105 has a shape of a stepped recess. The cavity 105 may comprise a trench or recess 103 formed in the first surface of the substrate 100. In addition, one or more through-holes 101 may extend between a bottom of the trench or recess 103 and the second surface of the substrate 100.

The isotope battery sheet 10c may include a trench 103 extending along the upper surface of the substrate 100 and a through-hole 101 extending from a bottom surface of the trench 103 to a lower surface of the substrate 100. As exemplarily shown in FIG. 6b, the trench 103 may extend longitudinally in the first direction R1, and the through-hole 101 may extend vertically from a bottom surface of the trench 103 in the substrate thickness direction T. The trench 103 may have a width extending in the second direction R2. In one or more aspects, a length of the trench 103 in the first direction R1 may be greater than the width of the trench 103. The first direction R1 is perpendicular to the second direction R2. In some aspects, a plurality of through-holes 101 may be arranged along the first direction R1 within a single trench 103, as exemplarily shown in FIGS. 6b and 6c.

A radiation source 200 may be positioned inside the trench 103 and the plurality of through-holes 101. The radiation source 200 may include a first portion 210 extending in the first direction R1 of the trench 103 and disposed within the trench 103. Further, the radiation source 200 may include a second portion 220 disposed within the through-hole 101 extending from the bottom of the trench 103 to the second—or bottom major—surface of the substrate 100.

A width of the first portion 210 of the radiation source 200 in the second direction R2 may be larger than the width of the second portion 220 of the radiation source 200 in the second direction R2. The width in the second direction R2 of the first region 110 of the substrate 100 corresponding to the first portion 210 of the radiation source may be larger than the width in the second direction R2 of the first region 110 of the substrate 100 corresponding to the second portion 220 of the radiation source 200.

The first region 110 of the substrate 100 may have a substantially constant thickness from the surface of the radiation source 200.

In one or more aspects, the isotope battery sheets 10c may be stacked without an intervening layer between adjacent isotope battery sheets 10c. In such aspects, the radiation source 200 of an isotope battery sheet 10c may contact a radiation source 200 of an adjacent isotope battery sheet 10c, the first region 110 of the substrate 100 of an isotope battery sheet 10c may contact the first region 110 of the substrate 100 of an adjacent isotope battery sheet 10c, and the second region 120 of the substrate 100 of an isotope battery sheet 10c may contact the second region 120 of the substrate 100 of an adjacent isotope battery sheet 10c. The uppermost isotope battery sheet 10c in the vertical direction V may comprise the first upper electrode 132 or the second upper electrode 134 and the lowest isotope battery sheet 10c in the vertical direction V may comprise the first lower electrode 152 or the second lower electrode 154. In aspects where the uppermost isotope battery sheet comprises the first upper electrode 132, the lowest isotope battery sheet may comprise the second lower electrode 154, and in aspects where the uppermost isotope battery sheet comprises the second upper electrode 134, the lowest isotope battery sheet may comprise the first lower electrode 152. Omitting the electrodes and connectors from the space between adjacent isotope battery sheets 10c may improve the energy density of the isotope battery 1d. Furthermore, it should be understood that electrodes and connectors may be omitted from isotope batteries according to other aspects of the present disclosure to improve the energy density of the isotope batteries.

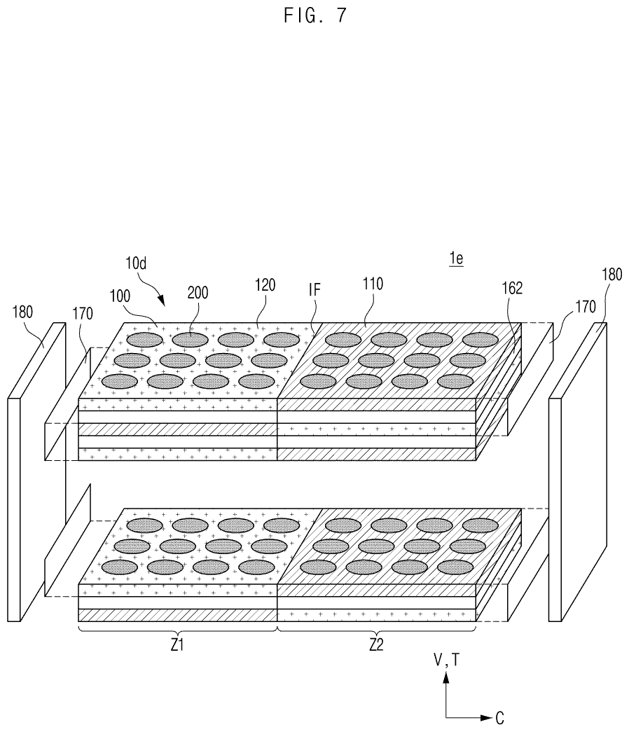

FIG. 7 is a side cross-sectional view illustrating an isotope battery 1e according to another aspect of the present disclosure.

Referring to FIG. 7, the isotope battery 1e includes a plurality of substrates 100 stacked in a vertical direction V to form a stack. As described above, the substrate 100 may have a first surface—or top major surface—and a second surface—or bottom major surface—opposite the first surface in a substrate thickness direction T. Further, each substrate 100 comprises a first region 110 of a first conductive type and a second region 120 of a second conductive type. The first region 110 and the second region 120 form a p-n junction at an interface IF between the first region 110 and the second region 120. In one or more aspects, the first region 110 and second region 120 of a respective substrate 100 may be arranged adjacent to each other in a substrate transverse direction C perpendicular to the substrate thickness direction T.

As schematically shown in FIG. 7, the interfaces IF of the substrates 100 stacked on top of one another are aligned in the vertical direction V, so that the interfaces (IF) overlap one another. This effectively divides the stack into a first zone Z1 and a second zone Z2 at opposite sides of the aligned interfaces IF. In other words, the first zone Z1 and the second zone Z2 that are neighboring with the aligned interfaces IF therebetween. Each of the plurality of substrates 100 corresponds to one isotope battery sheet 10d.

In one or more aspects, an insulating layer 162 may be interposed between substrates 100 that are stacked in the vertical direction V. For example, an insulating layer 162 may be positioned between two neighboring substrates 100 stacked in the vertical direction V. In some aspects, an insulating layer is positioned between each substrate of the plurality of substrates 100.

Each of the plurality of substrates 100 includes a plurality of radiation sources 200. The plurality of radiation sources 200 may extend through the substrate 100 in the vertical direction V. The plurality of the radiation sources 200 may extend through a portion of the substrate 100 in the vertical direction or through the entirety of the substrate 100 in the vertical direction. A plurality of radiation sources 200 may be included in each of the first zone Z1 and the second zone Z2 of the substrate 100. The radiation sources 200 in the first zone Z1 and the radiation sources 200 in the second zone Z2 may be arranged symmetrically with respect to the interface IF.

In a single substrate 100, the first zone Z1 and the second zone Z2 may have different conductivity types. For example, if the first zone Z1 is a first region 110 of a first conductive type, the second zone Z2 across the interface IF is a second region 120 of a second conductive type. Conversely, if the first zone Z1 is the second region 120 of the second conductive type, then the second zone Z2 across the interface IF is the first region 110 of the first conductive type.

In addition, two vertically neighboring substrates 100 in the first zone Z1 may have different conductivity types. For example, if the substrate 100 located at the upper part in the first zone Z1 is the first region 110 of the first conductivity type, the substrate 100 located directly thereunder in the first zone Z1 is the second region 120 of the second conductivity type. Similarly, if the substrate 100 located at the upper part in the first zone Z1 is the second region 120 of the second conductive type, then the substrate 100 located directly thereunder in the first zone Z1 is the first region 110 of the first conductive type.

Furthermore, the two vertically neighboring substrates 100 in the second zone Z2 may have different conductivity types. For example, if the substrate 100 located at the upper part in the second zone Z2 is the first region 110 of the first conductivity type, the substrate 100 located directly thereunder in the second zone Z2 is the second region 120 of the second conductivity type. Similarly, if the substrate 100 located at the upper part in the second zone Z2 is the second region 120 of the second conductive type, then the substrate 100 located directly thereunder in the second zone Z2 is the first region 110 of the first conductive type.

In the first zone Z1, two vertically neighboring substrates 100 may be electrically connected to each other. In addition, two vertically neighboring substrates 100 in the second zone Z2 may be electrically connected to each other. In some aspects, a pair of vertically neighboring substrates 100 may be electrically connected by a current collector 170. In some aspects, the current collector 170 may be on a side of the stacked semiconductor substrates 100. For example, the current collector 170 may connect lateral side end faces of neighboring substrates 100, wherein the lateral side end face of the respective substrate 100 extends between the first and the second surface of the respective substrate 100. In one or more aspects, the lateral side end face of a substrate 100 may be parallel to the interface IF. The current collector 170 connecting the semiconductor substrates 100 in the first zone Z1 may be disposed at an end of the substrate 100 farthest spaced apart from the second zone Z2. Furthermore, the current collector 170 connecting the semiconductor substrates 100 of the second zone Z2 may be disposed at an end of the substrate 100 farthest spaced apart from the first zone Z1.

In some aspects, a plurality of current collectors 170 may be alternately provided on both sides of the plurality of stacked isotope battery sheets 10d. For example, if the N^{th} and (N+1)^{th} isotope battery sheets 10d of the plurality of isotope battery sheets 10d are connected to a current collector 170 on a first side of the isotope battery sheets 10d, the (N+1)^{th} and (N+2)^{th} isotope battery sheets 10d may be connected to a current collector 170 on the opposite side. The outer side of the current collector 170 may be adjacent to an insulating bulkhead 180 to protect the current collector 170. In some aspects, the insulating bulkhead 180 may extend in a vertical direction to span an entire height of the plurality of stacked isotope battery sheets 10d.

In some aspects, the radiation sources 200 that penetrate each of the plurality of stacked semiconductor substrates 100 may be aligned in the vertical direction V. For example, the radiation sources 200 of the uppermost substrate 100 may be vertically aligned with the radiation sources 200 of the lowest semiconductor substrate 100 in the plurality of stacked semiconductor substrates 100. For example, the through holes in which the radiation sources 200 are received may be aligned in the vertical direction V, e.g., their center axes may be arranged coaxially or collinearly. Although not shown in FIG. 7, the plurality of through holes may be disposed in the substrate 100 such that their respective centers are located at the vertices of an imaginary equilateral triangle as previously described.

In some aspects, the radiation sources 200 may extend vertically through the plurality of stacked semiconductor substrates 100.

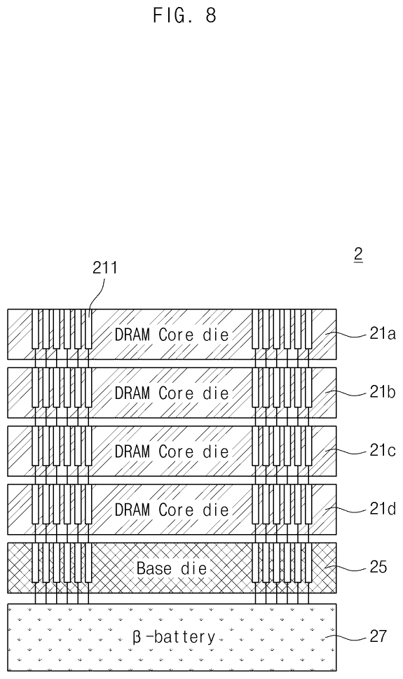

FIG. 8 is a conceptual diagram schematically illustrating a non-volatile memory device 2 according to an aspect of the present disclosure.

Referring to FIG. 8, the non-volatile memory device 2 may include a plurality of semiconductor memory devices 21a, 21b, 21c, 21d and a memory control device 25 configured to control the operation thereof.

In some aspects, the plurality of semiconductor memory devices 21a, 21b, 21c, 21d are vertically stacked, and each of them may have a through electrode 211. The through electrodes 211 may include a through silicon via (TSV). Each of the plurality of semiconductor memory devices 21a, 21b, 21c, 21d may be electrically connected to the memory control device 25 via the through electrode 211. Each of the plurality of semiconductor memory devices 21a, 21b, 21c, 21d may be a dynamic random access memory (DRAM) chip.

The non-volatile memory device 2 may further include an isotope battery 27 configured to power the memory control device 25. The isotope battery 27 may be any isotope battery according to the aspects the present disclosure. For example, the isotope battery 27 may be one of the isotope batteries 1, 1a, 1b, 1c, 1d, or 1e described above.

DRAM devices may have significantly higher read and write speeds compared to flash memory, but may have the disadvantage that the stored information is lost when the power is cut off. The non-volatile memory device 2 of FIG. 8 uses a DRAM device as a memory element, so it can be used as a portable data storage device because it has a high read speed and write speed, and because it is continuously powered by the isotope battery 27, the information stored in the DRAM device can be maintained without being lost.

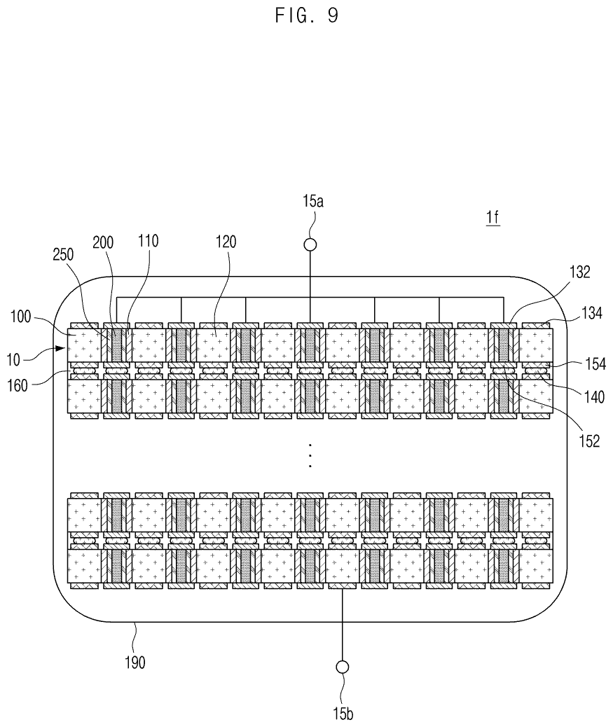

FIG. 9 is a cross-sectional view showing an isotope battery 1f according to an aspect of the present disclosure. The isotope battery 1f in FIG. 9 differs from the isotope battery 1 shown in FIG. 1a in that it further includes a photon generating layer 250 around the radiation source 200, and the following description will focus on these differences.

Referring to FIG. 9, the photon generating layer 250 may be any material layer capable of emitting photons in response to radiation particles, such as alpha particles, emitted from the radiation source 200. In some aspects, the radiation source 200 may be a material that emits alpha particles. Such materials have been described with reference to FIG. 1a, so further details are omitted here.

In one or more aspects, the photon generating layer 250 may comprise materials such as Ba₂Ca(BO₃)₂, BaHfO₃, BaI₂:Ce, BeO, BaF₂, BaMgF₄, Cs₂LiLuCi₆:Ce, K₂YF₅, KCaF₃, YI₃:Ce, but is not limited to these. Various examples of materials that may be included in the photon generating layer 250 are disclosed in the in the Berkeley Lab Inorganic Scintillator Library found at: https://scintillator.lbl.gov/inorganic-scintillator-library/.

The photon generating layer 250 can emit photons in response to incident alpha particles from the radiation source 200. The photons generated in the photon generating layer 250 can be incident on the interface between the first region 110 and the second region 120, and electrical energy can be generated by the photons.

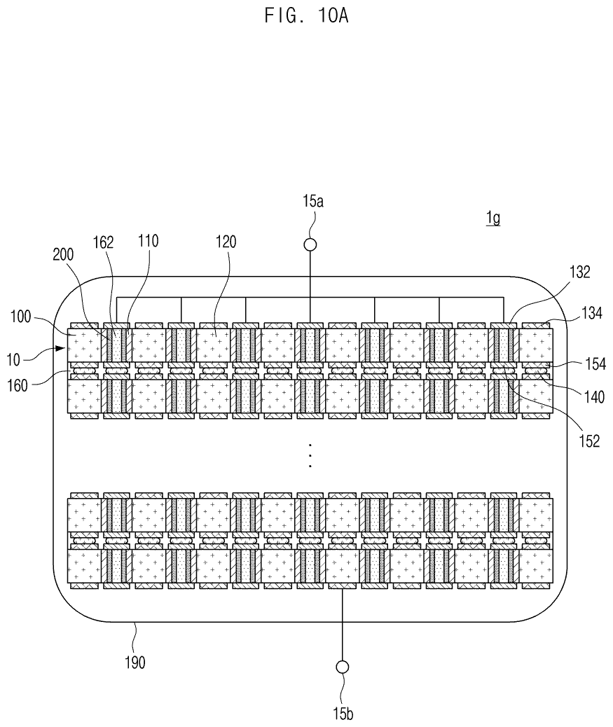

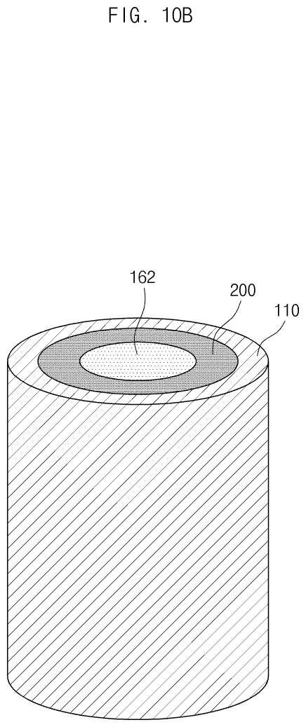

FIG. 10a is a side view of an isotope battery 1g according to another aspect of the present disclosure. FIG. 10b is an enlarged perspective view of the first region 110, radiation source 200, and insulating layer 162 of the isotope battery 1g shown in FIG. 10a. The isotope battery 1g shown in FIGS. 10a and 10b differs from the isotope battery 1 shown in FIG. 1a in that the radiation source 200 has an annular shape, and the following description will focus on this difference.

Referring to FIGS. 10a and 10b, the radiation source 200 may have a hollow tube shape with a central opening. The radiation source 200 may have a substantially uniform thickness and extend along a surface of first region 110. In some aspects, the central opening of the radiation source 200 may be filled with the insulating layer 162. In other aspects, the central portion may be filled with the substrate 100 or a semiconductor layer derived therefrom. In yet other aspects, the central portion may be filled with or may include a material serving to reflect the radiation (e.g., alpha rays, beta rays, etc.) emitted from the radioactive source 200. In that manner, such material may redirect incident radiation outwardly where it may better be absorbed by the substrate 100 having the interface between the first region 110 and the second region 120 (e.g., in the form of a p-n junction). Such reflective material is not limited to any particular material. In some examples, the material may be or may include material having radiation reflecting properties, such as copper, silver, or aluminum metal. In other examples, the material may be or may include material having radiation shielding properties, such as polymers like polyethylene, polypropylene, ethylene propylene copolymer, ethylene methacrylate copolymer, or polyethylene terephthalate.

In examples where the radiation source 200 has a hollow tube shape (e.g., filled with an insulating layer 162 in its interior), the amount of radiation source required to form the radiation source 200 can be reduced. Since the price of the radiation source is high, forming the radiation source 200 in this hollow shape allows the isotope battery 1g to be manufactured at a lower cost.

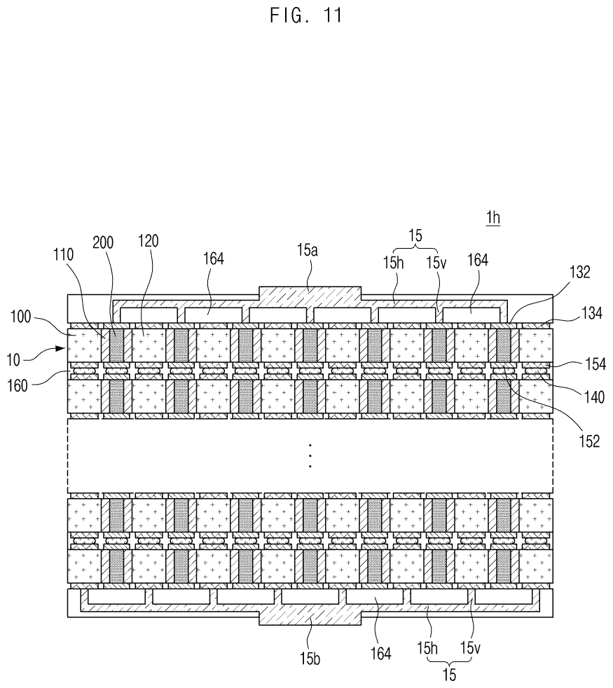

FIG. 11 is a cross-sectional view of an isotope battery 1h according to another aspect of the present disclosure. The isotope battery 1h shown in FIG. 11 differs from the isotope battery 1 shown in FIG. 1a in that the external electrodes 15a, 15b are further specified, and the following description will focus on these differences.

Referring to FIG. 11, the isotope battery 1h includes a first external electrode 15a and a second external electrode 15b for supplying electrical energy to an external load.

The first external electrode 15a includes conductive members 15 extending within an insulator 164 to connect the first upper electrodes 132 of the isotope battery sheet 10. The conductive members 15 are electrically connected only to the first upper electrodes 132.

In some aspects, the conductive members 15 may include one or more first conductive members 15h and one or more second conductive members 15v. The first conductive members 15h and the second conductive members 15v may extend in different directions within the insulator 164. The second conductive members 15v may electrically connect the first conductive members 15h and the first upper electrodes 132. The first conductive members 15h may be physically and/or electrically connected to the first external electrode 15a. In some aspects, the first conductive members 15h may extend in a horizontal direction and the second conductive members 15v may extend in a vertical direction, but aspects of the present disclosure are not limited thereto.

In some aspects, the second upper electrodes 134 of the isotope battery sheets 10 closest to the first external electrode 15a may be omitted.

The second external electrode 15b may also be electrically connected to the isotope battery sheets 10 in a manner similar to the first external electrode 15a. A person skilled in the art will be able to consider the wiring connection between the second external electrode 15b and the isotope battery sheets 10 by referring to the wiring connection between the first external electrode 15a and the isotope battery sheets 10 described above.

Although aspects of the present disclosure have been described in detail above, one of ordinary skill in the art to which the present disclosure belongs will be able to make many modifications to aspects of the present disclosure without departing from the spirit and scope of the present disclosure as defined in the appended claims. Accordingly, future modifications of aspects of the present disclosure will not depart from the technology of the present disclosure.

1. A battery apparatus comprising:
a plurality of semiconductor layers generally parallel to one another; and
a radioactive material embedded in at least part of the plurality of semiconductor layers and configured to emit beta rays into the at least part of the plurality of semiconductor layers,
wherein the plurality of semiconductor layers comprises a first semiconductor layer, a second semiconductor layer over the first semiconductor layer, and a third semiconductor layer over the second semiconductor layer,
wherein a plurality of bodies of the radioactive material is embedded in each of the first, second and third semiconductor layers:
such that, in each of the first, second and third semiconductor layers, each of the plurality of bodies extends along a thickness direction of the first semiconductor layer,
such that, in each of the first, second and third semiconductor layers, each of the plurality of bodies is distanced from adjacent bodies of the plurality of bodies in a plane perpendicular to the thickness direction,
such that, in each of the first, second and third semiconductor layers, each of the plurality of bodies is surrounded by a first type of semiconductor material which is further surrounded by a second type of semiconductor material,
such that a second body of the plurality of bodies embedded in the second semiconductor layer is connected to a first body of the plurality of bodies embedded in the first semiconductor layer and is further connected to a third body of the plurality of bodies embedded in the third semiconductor layer, which provides the first, second and third bodies respectively embedded in the first, second and third semiconductor layers are interconnected along the thickness direction,
such that the first type of semiconductor material surrounding the second body embedded in the second semiconductor layer is connected to the first type of semiconductor material surrounding the first body embedded in the first semiconductor layer and is further connected to the first type of semiconductor material surrounding the third body embedded in the third semiconductor layer, which provides the first type of semiconductor material surrounding the first, second and third bodies embedded respectively in the first, second and third semiconductor layers are interconnected along the thickness direction.

2. The apparatus of claim 1, wherein the first body embedded in the first semiconductor layer, the second body embedded in the second semiconductor layer, and the third layer embedded in the third semiconductor layer are aligned along the thickness direction.

3. The apparatus of claim 1, wherein the second body embedded in the second semiconductor layer contacts the first body embedded in the first semiconductor layer and further contacts the third body embedded in the third semiconductor layer, which provides the first, second and third bodies respectively embedded in the first, second and third semiconductor layers are interconnected along the thickness direction.

4. The apparatus of claim 1, wherein the first type of semiconductor material surrounding the second body embedded in the second semiconductor layer contacts the first type of semiconductor material surrounding the first body embedded in the first semiconductor layer and further contacts the first type of semiconductor material surrounding the third body embedded in the third semiconductor layer, which provides the first type of semiconductor material surrounding the first, second and third bodies embedded respectively in the first, second and third semiconductor layers are interconnected along the thickness direction.

5. The apparatus of claim 1, wherein the first semiconductor layer and the second semiconductor layer do not have an intervening layer therebetween.

6. The apparatus of claim 1, wherein the first semiconductor layer and the second semiconductor layer are distanced along the thickness direction.

7. The apparatus of claim 1, wherein the first semiconductor layer and the second semiconductor layer have an intervening layer therebetween.

8. The apparatus of claim 1, wherein the first semiconductor layer and the second semiconductor layer have a non-semiconductive intervening layer therebetween.

9. The apparatus of claim 1, wherein the first semiconductor layer and the second semiconductor layer are distanced in the thickness direction, wherein the first body embedded in the first semiconductor layer, the second body embedded in the second semiconductor layer, and the third layer embedded in the third semiconductor layer are aligned along the thickness direction.

10. The apparatus of claim 1, wherein the first semiconductor layer and the second semiconductor layer do not have an intervening layer therebetween, wherein the second body embedded in the second semiconductor layer contacts the first body embedded in the first semiconductor layer and further contacts the third body embedded in the third semiconductor layer, which provides the first, second and third bodies respectively embedded in the first, second and third semiconductor layers are interconnected along the thickness direction.

11. The apparatus of claim 1, wherein the plurality of bodies embedded in the third semiconductor layer individually comprises a top portion and a bottom portion that is closer to the second semiconductor layer than the top portion, wherein, in a cross-section taken by a plane parallel to the thickness direction, the top portion is wider than the bottom portion.

12. The apparatus of claim 1, wherein the first type of semiconductor material comprises an N-type semiconductor material, wherein the second type of semiconductor material comprise a P-type semiconductor material.

13. The apparatus of claim 1, wherein the first type of semiconductor material comprises a P-type semiconductor material, wherein the second type of semiconductor material comprise an N-type semiconductor material.

14. The apparatus of claim 1, wherein the plurality of bodies in the first semiconductor layer passes through the first semiconductor layer along the thickness direction.

15. The apparatus of claim 1, wherein the plurality of bodies is provided in through-holes extending along the thickness direction through the first type of semiconductor layer.

16. The apparatus of claim 1, wherein each of the plurality of bodies in the first semiconductor layer has a round shape in a first cross-section taken by a first imaginary plane that passes the first semiconductor layer and is perpendicular to the thickness direction.

17. The apparatus of claim 16, wherein, in the first cross-section the first type of semiconductor material has an annular shape surrounding each of the plurality of bodies in the first semiconductor layer, wherein the annular shape of the first type of semiconductor material is interposed between the radioactive material and the second type of semiconductor material.

18. The apparatus of claim 1, wherein, when viewed in the thickness direction, the plurality of bodies is regularly arranged in the first semiconductor layer such that gaps between two immediately neighboring ones of the plurality of bodies are generally the same.

19. The apparatus of claim 1, wherein the first type of semiconductor interconnected in the first, second and third semiconductor layers is electrically connected to a first electrode of the battery apparatus.

20. The apparatus of claim 1, wherein the second type of semiconductor material in the first semiconductor layer is electrically connected to a second electrode of the battery apparatus.
